(19) United States
(12) Patent Application Publication
(10) Pub. No.: US 2023/0011124 A1
(43) Pub. Date: Jan. 12, 2023

(54) PHOTOELECTRIC CONVERSION DEVICE, PHOTOELECTRIC CONVERSION SYSTEM, AND MOVING BODY

(71) Applicant: CANON KABUSHIKI KAISHA, Tokyo (JP)

(72) Inventor: Yasuhiro Nagatomo, Kanagawa (JP)

(21) Appl. No.: 17/854,281

(22) Filed: Jun. 30, 2022

(30) Foreign Application Priority Data
Jul. 8, 2021 (JP) 2021-113492

(51) Int. Cl. H01L 27/146; B60W 30/09

(52) U.S. Cl. CPC H01L 27/14629; H01L 27/14623; B60W 30/09; H01L 27/14649; H01L 27/1464; H01L 27/1463; B60W 2420/403

(57) ABSTRACT

A photoelectric conversion device includes a semiconductor layer formed of silicon, a plurality of pixels formed in the semiconductor layer, and a pixel separation portion is formed to separate each of the plurality of pixels, wherein the pixel separation portion includes a metal filling portion and a dielectric film provided on a side portion of the metal filling portion, a material of the metal filling portion is copper, a material of the dielectric film is a silicon oxide, and a thickness of the dielectric film is not less than 50 nm and not more than 270 nm.

### BACKGROUND I/F THE INVENTION

### Field of the Invention

The present invention relates to a photoelectric conversion device, a photoelectric conversion system, and a moving body.

### Description of the Related Art

As a technology for improving a sensitivity of a photoelectric conversion device (solid-state imaging element) to light, a back-side-illumination CMOS image sensor (see Japanese Patent Application Publication No. 2019-46960) having a periodic uneven structure portion provided on a light receiving surface is known. Light incident on the photoelectric conversion device is diffracted by the periodic uneven structure portion. The diffracted light is reflected by a pixel separation portion having a trenched structure to be confined to the inside of one pixel. When the periodic uneven structure portion is provided on the light receiving surface, an optical path length is longer than in a case where the periodic uneven structure portion is not provided on the light receiving surface and light travels straight in the pixel. Consequently, an improved sensitivity to a near-infrared region to which silicon exhibits a particularly small light absorption coefficient can be expected.

In Japanese Patent Application Publication No. 2019-46960, when DTI (Deep Trench Isolation) serving as the pixel separation portion is filled with a metal material having an excellent light shielding property, it is possible to suppress optical crosstalk (light leakage) to an adjacent pixel and reduce optical color mixing and resolution deterioration. However, under the influence of light absorption by the metal material, a sensitivity of a photoelectric conversion device to light may decrease.

Meanwhile, when the DTI is filled with a dielectric material, the effect of such light absorption as that by the metal material is smaller, and accordingly it is possible to improve the sensitivity of the photoelectric conversion device. However, the dielectric material has a light shielding property inferior to that of the metal material, and consequently the optical crosstalk may possibly cause the optical color mixing or the resolution deterioration.

### SUMMARY I/F THE INVENTION

It is therefore an object of the present technical disclosure to simultaneously improve a sensitivity of a photoelectric conversion device to light in a near-infrared region and suppress optical crosstalk.

An aspect of the present technical disclosure is a photoelectric conversion device comprising: a semiconductor layer formed of silicon; a plurality of pixels formed in the semiconductor layer; and a pixel separation portion is formed to separate each of the plurality of pixels, wherein, the pixel separation portion includes a metal filling portion and a dielectric film provided on a side portion of the metal filling portion, a material of the metal filling portion is copper, a material of the dielectric film is a silicon oxide, and a thickness of the dielectric film is not less than 50 nm and not more than 270 nm.

An aspect of the present technical disclosure is a photoelectric conversion device comprising: a semiconductor layer formed of silicon; a plurality of pixels formed in the semiconductor layer; and a pixel separation portion is formed to separate each of the plurality of pixels, wherein, the pixel separation portion includes a metal filling portion and a dielectric film provided on a side portion of the metal filling portion,

a material of the metal filling portion is tungsten, a material of the dielectric film is a silicon oxide, and a thickness of the dielectric film is not less than 130 nm and not more than 250 nm.

An aspect of the present technical disclosure is a photoelectric conversion device comprising: a semiconductor layer formed of silicon; a plurality of pixels formed in the semiconductor layer; and a pixel separation portion is formed to separate each of the plurality of pixels, wherein, the pixel separation portion includes a metal filling portion and a dielectric film provided on a side portion of the metal filling portion, a material of the metal filling portion is cobalt, a material of the dielectric film is a silicon oxide, and a thickness of the dielectric film is not less than 110 nm and not more than 270 nm.

An aspect of the present technical disclosure is a photoelectric conversion device comprising: a semiconductor layer formed of silicon; a plurality of pixels formed in the semiconductor layer; and a pixel separation portion is formed to separate each of the plurality of pixels, wherein, the pixel separation portion includes a metal filling portion and a dielectric film provided on a side portion of the metal filling portion, a material of the metal filling portion is aluminum, a material of the dielectric film is a silicon oxide, and a thickness of the dielectric film is not less than 60 nm and not more than 250 nm.

Further features of the present invention will become apparent from the following description of exemplary embodiments with reference to the attached drawings.

### BRIEF DESCRIPTION I/F THE DRAWINGS

FIG. 1 is a block diagram of a photoelectric conversion device;

FIG. 2 is a block diagram of a pixel;

FIGS. 3A to 3C are diagrams illustrating a problem of the photoelectric conversion device to be solved;

FIG. 4 is a cross-sectional view of a photoelectric conversion device according to a first embodiment;

FIG. 5A is a diagram illustrating a transmittance of DTI according to the first embodiment;

FIG. 5B is a diagram illustrating a reflectance of the DTI according to the first embodiment;

FIGS. 6A and 6B are diagrams illustrating a relationship between a thickness of a DTI side portion and the reflectance of the DTI according to the first embodiment;

FIG. 7A is a diagram illustrating a transmittance of DTI according to a second embodiment;

FIG. 7B is a diagram illustrating a reflectance of the DTI according to the second embodiment;

FIGS. 8A and 8B are diagrams illustrating a relationship between a thickness of a DTI side portion and the reflectance of the DTI according to the second embodiment;

FIG. 9A is a diagram illustrating a transmittance of DTI according to a third embodiment;

FIG. 9B is a diagram illustrating a reflectance of the DTI according to the third embodiment;

FIGS. 10A and 10B are diagrams illustrating a relationship between a thickness of a DTI side portion and the reflectance of the DTI according to the third embodiment;

FIG. 11A is a diagram illustrating a transmittance of DTI according to a fourth embodiment;

FIG. 11B is a diagram illustrating a reflectance of the DTI according to the fourth embodiment;

FIGS. 12A and 12B are diagrams illustrating a relationship between a thickness of a DTI side portion and the reflectance of the DTI according to the fourth embodiment;

FIG. 13 is a diagram illustrating a photoelectric conversion system according to a fifth embodiment;

FIG. 14A is a diagram illustrating a photoelectric conversion system according to a sixth embodiment;

FIG. 14B is a diagram illustrating a moving body according to the sixth embodiment;

FIG. 15 is a diagram illustrating a distance image sensor according to a seventh embodiment;

FIG. 16 is a diagram illustrating an endoscopic surgical system according to an eighth embodiment; and

FIG. 17A and FIG. 17B are diagrams illustrating smart glasses according to a ninth embodiment.

### DESCRIPTION I/F THE EMBODIMENTS

First, a description will be given of terminology used in the present specification. In the following, a “back side” refers to a light incident side (light incident surface side) of a photoelectric conversion device which is a back-side-illumination CMOS image sensor. Meanwhile, a “front side” refers to a side opposite to the back side. In the photoelectric conversion device, a pixel separation portion having a trenched structure may be referred to also as DTI (Deep Trench Isolation).

In the following embodiments, for the DTI filled with a metal material, a thickness of a dielectric film to be provided on a side portion of the DTI is set equal to or more than a predetermined thickness. This allows the DTI to have both of a high light shielding property and a low light absorbing property, and therefore it is possible to simultaneously improve a sensitivity of the photoelectric conversion device and suppress optical crosstalk. Note that, in the following, a thickness of a DTI inner portion or a thickness of a DTI side portion is a length in a direction perpendicular to a direction in which the DTI extends. Otherwise, it can also be said that the thickness of the DTI inner portion or the thickness of the DTI side portion is a length in a direction perpendicular to a direction in which individual layers of the photoelectric conversion device are stacked and a length in a direction parallel to a main surface of a substrate of the photoelectric conversion device.

Note that, in each of the embodiments described below, a description will be given with emphasis on an imaging device as an example of the photoelectric conversion device. However, each of the embodiments is not limited to the imaging device, and is also applicable to another example of the photoelectric conversion device. Examples of the photoelectric conversion device include a distance measurement device (a device for distance measurement using focal detection or TOF (Time of Flight) or the like), a light measurement device (a device for measurement of an amount of incident light or the like), and the like.

In the present specification, “in plan view” refers to viewing an object in a direction perpendicular to a surface opposite to a light incident surface of a semiconductor layer described later. Meanwhile, a cross section refers to a surface in the direction perpendicular to the surface opposite to the light incident surface of the semiconductor layer. Note that, when the light incident surface of the semiconductor layer is a rough surface when viewed microscopically, “in plan view” is defined on the basis of the light incident surface of the semiconductor layer when viewed macroscopically.

(Problem Occurring in Photoelectric Conversion Device) First, a description will be given of a mechanism in which light absorption or optical crosstalk to an adjacent pixel occurs in the DTI, and a problem occurring in a photoelectric conversion device to which none of the following embodiments is applied. Typically, a side portion and a bottom surface of the DTI are covered with a thin oxide film. In addition, the DTI inner portion is filled with a material such as a dielectric material, a metal material, or polysilicon. Note that, in a part of the DTI, a gap may also be left.

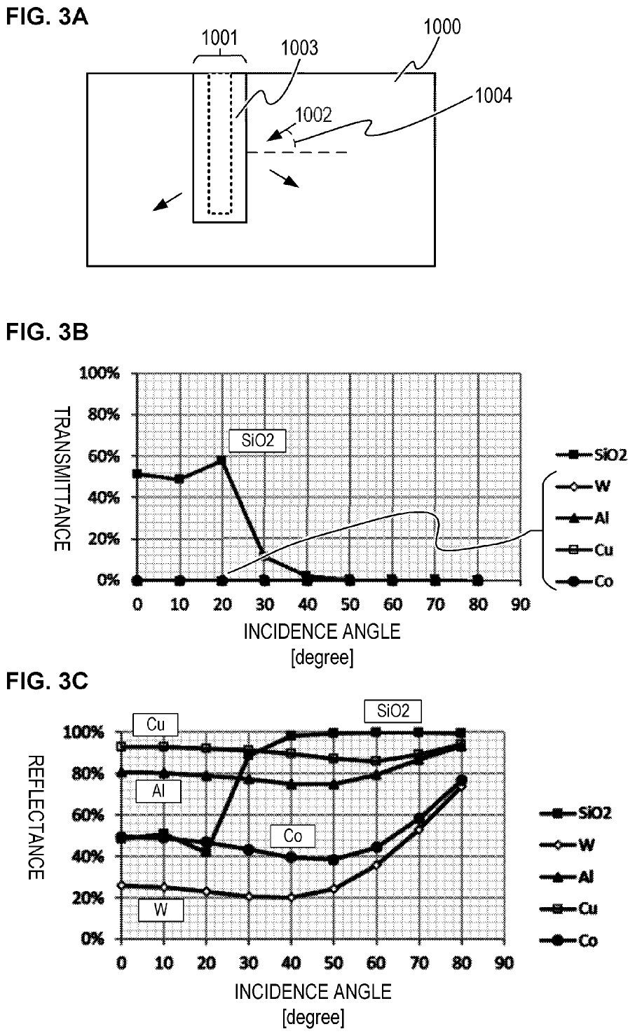

FIG. 3A illustrates a part of the semiconductor layer in the photoelectric conversion device. FIG. 3A is a cross-sectional schematic diagram illustrating transmission and reflection of light 1002 incident from silicon 1000 on DTI 1001. An incidence angle 1004 is an incidence angle of the light 1002.

When a transmittance of the DTI 1001 is high, a large number of components of the light 1002 are transmitted by the DTI 1001 to increase optical crosstalk from one of pixels to a pixel adjacent thereto. Meanwhile, when a reflectance of the DTI 1001 is high, the light 1002 is confined to the inside of the one pixel to contribute to an improvement in the sensitivity of the photosensitive conversion device to light. Accordingly, it is preferable to increase the reflectance of the DTI 1001, while reducing the transmittance thereof. Note that the transmittance and the reflectance depend on a configuration (thickness, material, and layer configuration) of the DTI 1001, an optical wavelength, the incidence angle, or the like.

FIGS. 3B and 3C illustrate a result of calculation of incidence angle dependency of the transmittance and the reflectance when light at a wavelength of 940 nm included in light in a near-infrared region is incident from the silicon 1000 on the DTI 1001. It is assumed herein that a thickness of the DTI 1001 is 200 nm, and SiO₂ having a thickness of 10 nm is deposited on a DTI side portion 1003. FIGS. 3B and 3C illustrate graphs obtained by varying a material with which the DTI 1001 except for a region thereof where SiO₂ is deposited is to be filled and comparing the transmittances and the reflectances. Note that, for simplification, the calculation was performed on the assumption that a height of the DTI 1001 (length thereof in a direction in which the DTI 1001 extends) was infinite. The material with which the DTI 1001 was filled is SiO₂ (silicon dioxide or silicon oxide), W (tungsten), Al (aluminum), Cu (copper), or Co (cobalt).

When the DTI 1001 is filled with SiO₂ as a dielectric material, the light 1002 is reflected by the DTI 1001 on the basis of a diffraction index difference between silicon and SiO₂. When the light 1002 is visible light or infrared light, there is substantially no light absorption of the light 1002 by SiO₂, and consequently the components of the light 1002 that are not reflected by the DTI 1001 are undesirably transmitted to the adjacent pixel. When the incidence angle 1004 has a value satisfying conditions for total reflection, the light 1002 is completely reflected. Referring to FIGS. 3B and 3C, when the incidence angle is 40 degrees or less, a part of the light 1002 is transmitted by the DTI 1001. Meanwhile, the light 1002 incident at an incidence angle larger than 40 degrees is 100% reflected by the DTI 1001.

Note that a critical angle of the total reflection theoretically calculated from refraction indices of silicon and SiO₂ when the wavelength of the light is 940 nm is 23.8 degrees, but an incidence angle at which the light is totally reflected in a real situation is larger than 23.8 degrees. Specifically, an angle close to 40 degrees serves as the critical angle of real total reflection. This may be conceivably because, since the thickness of the DTI 1001 is finite, an evanescent wave having leaked into SiO₂ reaches silicon of the adjacent pixel to be converted to propagation light. The evanescent wave mentioned herein is a special electromagnetic wave that is generated when the light is incident at an incidence angle equal to or more than the theoretical critical angle from a high refraction index phase into a low refraction index phase, and then reflected.

Thus, when the incidence angle 1004 is large in the photoelectric conversion device in which the DTI 1001 is filled with the dielectric material (SiO₂), a majority of the components of the light 1002 are reflected by the DTI 1001 without being lost. Meanwhile, when the incidence angle 1004 is small, a problem is encountered in which the optical crosstalk to the adjacent pixel occurs.

Meanwhile, when the DTI 1001 is filled with the metal material, the components of the light 1002 that are not reflected by the DTI 1001 are substantially entirely absorbed by the metal. Referring to FIGS. 3B and 3C, the transmittance to the light 1002 is substantially zero irrespective of the incidence angle 1004. In addition, unlike in a case where the DTI 1001 is filled with the dielectric material, even when the incidence angle 1004 varies, the reflectance of the DTI 1001 has not so significantly varied. Note that the reflectance of the DTI 1001 greatly differs from one metal material to another, but has not reached 100% even when the metal material is Cu having the highest reflectance. This is because the light absorption by the metal leads to a light loss. Occurrence of a loss in the light 1002 when the light 1002 reaches the DTI 1001 leads to a reduction in the sensitivity of the photoelectric conversion device.

In the case where the DTI 1001 is filled with the metal material as described above, compared to the case where the DTI 1001 is filled with the dielectric material, it is advantageously possible to perform stable light shielding even when the incidence angle 1004 has any value, but a problem of a sensitivity reduction is eventually encountered.

(Circuit Configuration of Photoelectric Conversion Device) A description will be given of a circuit configuration of the photoelectric conversion device according to each of the following embodiments. The photoelectric conversion device is a back-side-illumination solid-state imaging element. The photoelectric conversion device includes an avalanche diode. The avalanche diode has a Geiger mode in which, when a reversely biased voltage is supplied thereto, the avalanche diode is operated in a state where a potential difference between an anode and a cathode is higher than a breakdown voltage. The avalanche diode also has a linear mode in which the avalanche diode is operated in a state where the potential difference between the anode and the cathode is in the vicinity of or not more than the breakdown voltage.

The avalanche diode operated in the Geiger mode is referred to as a SPAD (Single Photon Avalanche Diode). For example, an anode voltage is −30 V, while a cathode voltage is 1 V. The avalanche photodiode (APD) may be operated in the linear mode or operated in the Geiger mode. In the following, the photoelectric conversion device includes the SPAD (Single Photon Avalanche Diode) that counts the number of photons incident on the avalanche diode. Note that the photoelectric conversion device need not be a photoelectric conversion device including the avalanche diode, and may also be a distance measurement sensor using LiDAR (Light Detection and Ranging) or an infrared sensor.

In the following description, the anode of the avalanche diode is placed at a fixed potential, and a signal is retrieved from a cathode side. Therefore, a first-conductivity-type semiconductor region using, as majority carriers, carriers having the same conductivity type as that of a signal carrier is an N-type semiconductor region, while a second-conductivity-type semiconductor region is a P-type semiconductor region. It may also be possible to place the cathode of the avalanche diode at a fixed potential and retrieve the light from an anode side. In this case, the first-conductivity-type semiconductor region using, as the majority carriers, the carriers having the same conductivity type as that of the signal carrier is the P-type semiconductor region, while the second-conductivity-type semiconductor region is the N-type semiconductor region.

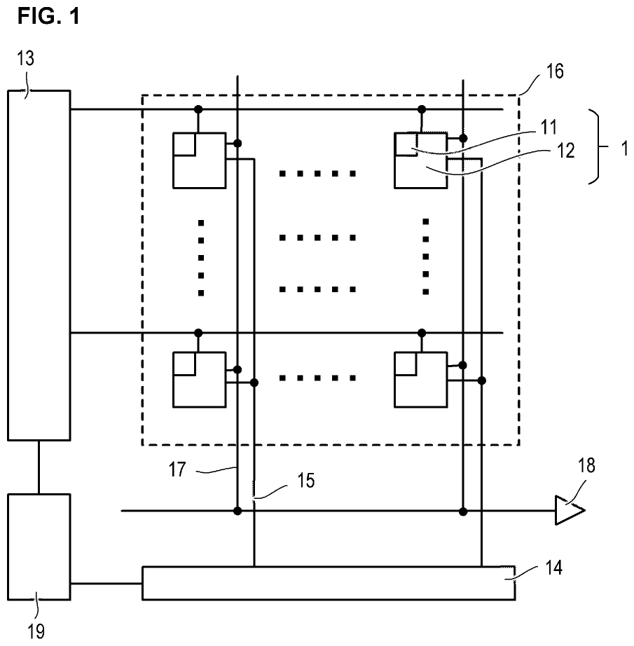

FIG. 1 is a block diagram of the photoelectric conversion device. The photoelectric conversion device includes a pixel unit 16, a control pulse generation unit 19, a horizontal scanning circuit unit 14, a control line 15, a signal line 17, a vertical scanning circuit unit 13, and an output circuit 18.

In the pixel unit 16, a plurality of pixels 1 are arranged in a two-dimensional configuration. Each one of the pixels 1 includes a photoelectric conversion unit 11 and a pixel signal processing unit 12. The photoelectric conversion unit 11 converts light to an electric signal. The pixel signal processing unit 12 outputs the electric signal resulting from the conversion to the output circuit 18.

Each of the vertical scanning circuit unit 13 and the horizontal scanning circuit unit 14 receives a control pulse supplied from the control pulse generation unit 19 to supply the control pulse to each of the pixels 1. For the vertical scanning circuit unit 13, a logic circuit such as a shift register or an address decoder is used.

The signal line 17 supplies, as a potential signal, a signal output from the pixel 1 selected by the vertical scanning circuit unit 13 to a circuit in a stage subsequent to the pixel 1.

The output circuit 18 includes a buffer amplifier, a differential amplifier, or the like. The output circuit 18 outputs the signal output from each of the pixels 1 to a recording unit or a signal processing unit outside the photoelectric conversion device.

In FIG. 1, the pixels 1 in the pixel unit 16 may also be arranged in a one-dimensional configuration (linear configuration). Alternatively, it may also be possible to divide a plurality of rows of the pixels in the pixel unit 16 into blocks and dispose the vertical scanning circuit unit 13 and the horizontal scanning circuit unit 14 for each of the blocks. Still alternatively, it may also be possible to dispose the vertical scanning circuit unit 13 and the horizontal scanning circuit unit 14 for each of the rows of the pixels.

The function of the pixel signal processing unit 12 need not necessarily be provided for each of the pixels 1 on a one-to-one basis. For example, it may also be possible that the one pixel signal processing unit 12 is shared by the plurality of pixels 1, and signal processing is sequentially performed. To increase an aperture ratio of the photoelectric conversion unit 11, the pixel signal processing unit 12 may also be provided on a semiconductor substrate different from that of the photoelectric conversion unit 11. In this case, the photoelectric conversion unit 11 and the pixel signal processing unit 12 are electrically connected via a connecting wire provided on a per pixel basis. The vertical scanning circuit unit 13, the horizontal scanning circuit unit 14, and the signal line 17 may also be provided on the different semiconductor substrate as described above.

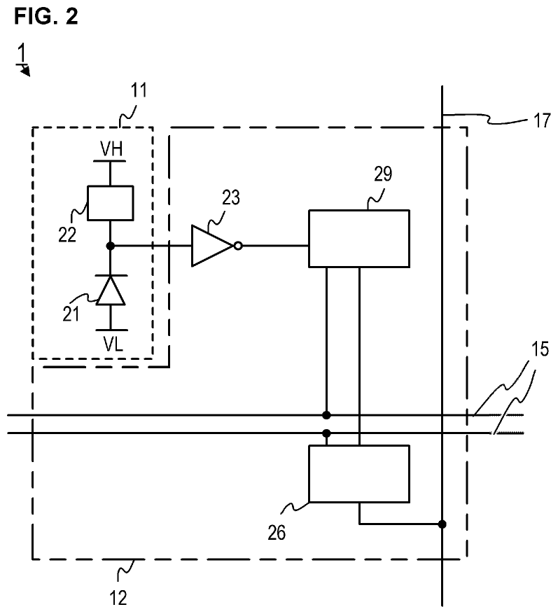

FIG. 2 is a block diagram of each of the pixels 1 including an equivalent circuit. In FIG. 2, each one of the pixels 1 includes the photoelectric conversion unit 11 and the pixel signal processing unit 12. The photoelectric conversion unit 11 includes an avalanche diode 21 and a quench element 22. The avalanche diode 21 generates, through photoelectric conversion, a charge pair corresponding to incident light. To a cathode of the avalanche diode 21, a potential based on a potential VH higher than a potential VL supplied to an anode is supplied. Then, to the anode and the cathode of the avalanche diode 21, potentials are supplied such that a reverse bias which causes avalanche multiplication of photons incident on the avalanche diode 21 is applied. By causing the photoelectric conversion in a state where such reversely biased potentials are supplied, charges caused by the incident light undergo the avalanche multiplication to generate an avalanche current.

Note that, in a case where the reversely biased potentials are supplied, when a potential difference between the anode and the cathode is larger than the breakdown voltage, the avalanche diode is operated in the Geiger mode. The avalanche diode that uses the Geiger mode operation to detect an extremely weak signal on a single photon level at a high speed is the SPAD (Single Photon Avalanche Diode).

The quench element 22 is connected to a power source that supplies the high potential VH and to the avalanche diode 21. The quench element 22 includes a P-type MOS transistor, a resistive element diffusion resistance, or the like. When a photocurrent is multiplied by the avalanche multiplication in the avalanche diode, a current obtained due to the multiplied signal charges flows in a connection node between the avalanche diode 21 and the quench element 22. A voltage drop due to this current lowers the potential at the cathode of the avalanche diode 21, and the avalanche diode 21 no longer forms an electronic avalanche. As a result, the avalanche multiplication in the avalanche diode 21 is stopped. Subsequently, the potential VH from the power source is supplied to the cathode of the avalanche diode 21 via the quench element 22, and consequently the potential supplied to the cathode of the avalanche diode 21 returns to the potential VH. In other words, an operating region of the avalanche diode 21 comes back to the Geiger mode operation. Thus, the quench element 22 functions as a load circuit (quench circuit) during signal amplification due to the avalanche multiplication, and has a function of suppressing the avalanche multiplication (quenching operation). The quench element also has a function of suppressing the avalanche multiplication, and then bringing the operating region of the avalanche diode back to the Geiger mode.

The pixel signal processing unit 12 includes a waveform shaping unit 23, a counter circuit 29, and a selection circuit 26. The waveform shaping unit 23 shapes a potential change at the cathode of the avalanche diode 21 obtained at the time of photon detection to output a pulse signal. As the waveform shaping unit 23, e.g., an inverter circuit is used. In the example shown above, the one inverter is used as the waveform shaping unit 23, but it may also be possible to use a circuit in which a plurality of inverters are connected in series or another circuit having a waveform shaping effect.

The pulse signal output from the waveform shaping unit 23 is counted by the counter circuit 29. When the counter circuit 29 is, e.g., an N-bit counter (N: a positive integer), the counter circuit 29 can count pulse signals resulting from a signal photon up to a maximum of about a number obtained by raising 2 to the N-th power. The counted signal is held as the detected signal. When a control pulse pRES is supplied via the control line 15, the signal held by the counter circuit 29 is reset.

To the selection circuit 26, from the vertical scanning circuit unit 13 in FIG. 1, a control pulse pSEL is supplied via the control line 15 in FIG. 2. The selection circuit 26 switches between electrical connection and non-connection between the counter circuit 29 and the signal line 17. The selection circuit 26 includes, e.g., a buffer circuit for outputting a signal or the like.

It may also be possible to provide a switch such as a transistor between the quench element 22 and the avalanche diode 21 or between the photoelectric conversion unit 11 and the pixel signal processing unit 12 to switch the electrical connection. Likewise, it may also be possible to use a switch such as a transistor to electrically switch a supply of the high potential VH or the low potential VL given to the avalanche diode 21.

In the pixel unit 16 in which the plurality of pixels 1 are arranged in rows and columns, it may also be possible to acquire a captured image by a rolling shutter operation of sequentially resetting counts in the counter circuits 29 on a per row basis and sequentially outputting the signals held in the counter circuits 29 on a per row basis.

Alternatively, it may also be possible to acquire the captured image by a global electronic shutter operation of simultaneously resetting the counts in the counter circuits 29 in all the pixel rows and sequentially outputting the signals held by the counter circuits 29 on a per row basis. Note that, when the global electronic shutter operation is to be performed, it is preferable to provide a means for switching between a case where the counter circuits 29 perform counting and a case where the counter circuits 29 do not perform counting. Examples of the switching means include the switch described previously.

In the description given above, the configuration in which the captured image is acquired using the counter circuits 29 is shown. However, it may also be possible to configure the photoelectric conversion device such that a time-to-digital conversion circuit (Time to Digital Converter hereinafter abbreviated as TDC) and a memory are used instead of the counter circuits 29 to acquire pulse detection timing.

At this time, timing of generation of the pulse signal output from the waveform shaping unit 23 is converted by the TDC to a digital signal. To the TDC, for measurement of the timing of the pulse signal, a control pulse pREF (reference signal) is supplied from the vertical scanning circuit unit 13 in FIG. 1 via a drive line. The TDC uses the control pulse pREF as a reference to acquire, as the digital signal, a signal when a relative time is used as timing of reception of the signal output from each of the pixels via the waveform shaping unit 23.

### First Embodiment

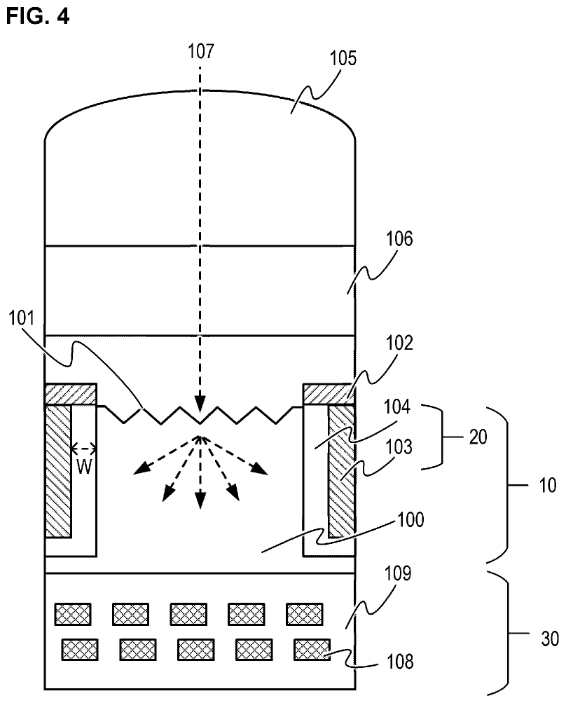

Referring to FIGS. 4 to 6B, an example of the photoelectric conversion device in which the DTI is provided as the pixel separation portion between the pixels in the photoelectric conversion device will be described. In the first embodiment, in the DTI, a thickness of the dielectric film provided on a side portion of a metal filling portion has a predetermined value or more to be able to simultaneously achieve a high light shielding property and a low light absorbing property of the DTI with respect to the light in the near-infrared region (light at a wavelength of not less than 750 nm and not more than 2500 nm). It is assumed hereinbelow that, for detection of the light in the near-infrared region, a pixel size in the photoelectric conversion device including the SPAD according to the first embodiment is not less than 5 μm and not more than 10 Accordingly, even when a width of the DTI is somewhat large, the effect on a reduction in a sensitivity of a photoelectric conversion unit 201 is small. Meanwhile, it is assumed that a pixel size in a conventional photoelectric conversion device for use in a smartphone or the like is not more than 1 Accordingly, in the conventional photoelectric conversion device for use in a smartphone or the like, it was not assumed to increase the thickness of the DTI (to, e.g., 200 nm or more) or increase the thickness of the dielectric material, since the increased thickness of the DTI or the dielectric material affects the sensitivity reduction.

FIG. 4 is a cross-sectional schematic diagram of one of pixels in the photoelectric conversion device (solid-state sensing element) according to the first embodiment. The photoelectric conversion device includes a semiconductor layer 10, a light shielding film 102, a microlens 105, a color filter 106, metal wires 108, and an interlayer insulating film 109. The semiconductor layer 10 is formed of the silicon 100. In the semiconductor layer 10, a periodic uneven structure portion 101 and a DTI 20 (pixel separation portion) are formed. The semiconductor layer 10 includes at least the photoelectric conversion unit 201 described above. The DTI 20 includes a DTI inner portion 103 and a DTI side portion 104. Note that, in plan view, the DTI 20 surrounds the pixels to separate the individual pixels from each other.

Incident light 107 is transmitted by the microlens 105 and the color filter 106 to be incident on the silicon 100 from a back side of the photoelectric conversion device. It is assumed that, in each of the embodiments, a wavelength of the incident light 107 after being transmitted by the color filter 106 is 940 nm.

In a back-side interface of the silicon 100 (semiconductor layer 10), the periodic uneven structure portion 101 is formed. The periodic uneven structure portion 101 is formed by dry etching or wet etching performed on the interface of the silicon 100, periodic formation of depressed portions, and embedding of an insulating material such as SiO₂ therein. The incident light 107 is diffracted by the periodic uneven structure portion 101 to be bent in various directions. The incident light 107 advancing in an oblique direction is reflected by the DTI 20 to zigzag in the silicon 100. As a result, an effective optical path length of the incident light 107 when the incident light 107 passes through an inner portion of the silicon 100 is elongated. This improves the sensitivity of the photoelectric conversion device particularly to the incident light 107 in the near-infrared region to which the silicon 100 exhibits a small absorption coefficient.

The DTI side portion 104 is a thin film made of SiO₂ as a dielectric material and surrounds the DTI inner portion 103. The DTI inner portion 103 is a metal filling portion (region) filled with Cu as a metal material. A thickness of the DTI inner portion 103 (metal filling portion filled with Cu) is 180 nm. Over the DTI 20, the light shielding film 102 is provided. A material forming the light shielding film 102 may be the same as the meal material with which the DTI inner portion 103 is filled or may also be a different material. On a surface side of the silicon 100, a wiring layer 30 including the metal wires 108 and the interlayer insulating film 109 is disposed. The wiring layer 30 may also have a reflector (wiring) that reflects the incident light 107 incident on the wiring layer 30.

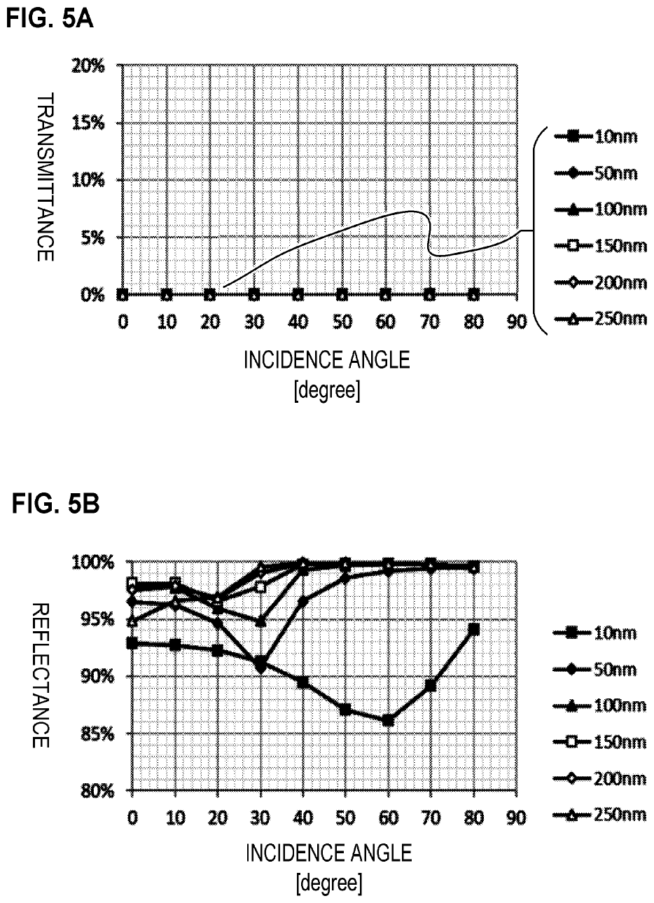

Consideration is given herein to a case where the incident light 107 diffracted by the periodic uneven structure portion 101 reaches the DTI 20. FIGS. 5A and 5B illustrate a result of calculating a transmittance and a reflectance of the DTI 20 with respect to light at a wavelength of 940 nm (the light at this wavelength is hereinafter referred to as “near-infrared light”) when the thickness of the DTI side portion 104 was varied. The thickness of the DTI side portion 104 is a thickness of the DTI side portion 104 surrounding the DTI inner portion 103, which is a length denoted by a width W in FIG. 4. Note that the incident light 107 is not limited to the light at the wavelength of 940 nm as long as the incident light 107 is the light in the near-infrared region (light at a wavelength of not less than 750 nm and not more than 2500 nm). When the incident light 107 is light at a wavelength of not less than 850 nm, the same effects as obtained in the first embodiment can favorably be obtained. As described above, the near-infrared light diffracted by the periodic uneven structure portion 101 is incident at various angles on the DTI 20. FIGS. 5A and 5B illustrate the result of calculating the transmittance and the reflectance at each of incidence angles of the near-infrared light. Note that the incidence angle is the angle (angle at which the incident light 107 is incident from outside the DTI 20 on the DTI 20) described with reference to FIG. 3A.

As illustrated in FIG. 5A, the transmittance of the DTI 20 to the near-infrared light is substantially zero irrespective of the thickness of the DTI side portion 104 and the incidence angle. Meanwhile, as illustrated in FIG. 5B, the reflectance of the DTI 20 to the near-infrared light has a value increasing at substantially all the incidence angles as the thickness of the DTI side portion 104 increases to 10 nm, 50 nm, and 100 nm. In particular, in a range in which the incidence angle is 40 degrees or more, when the thickness of the DTI side portion 104 progressively increases, the reflectance reaches substantially 100%. Note that the light neither transmitted nor reflected has been absorbed by the DTI 20.

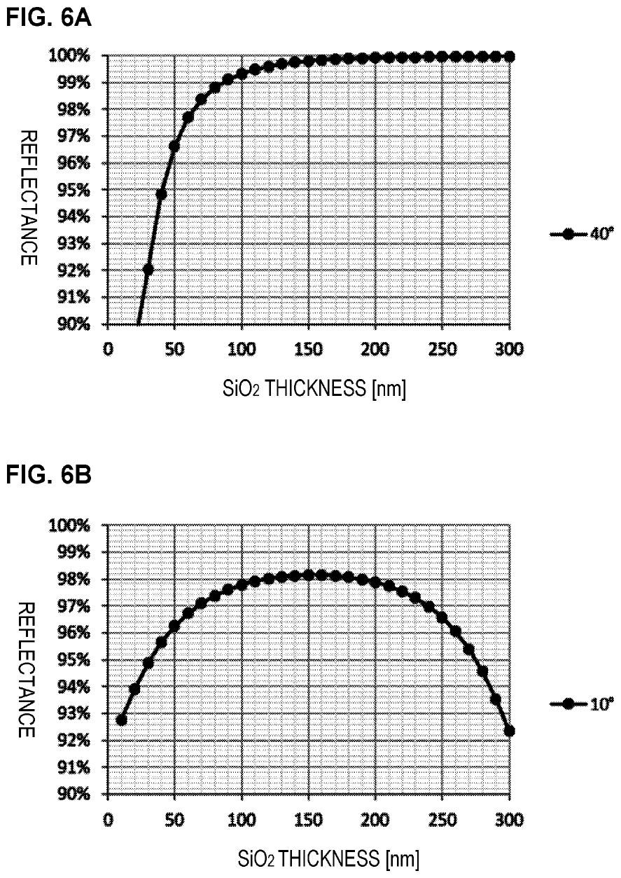

FIGS. 6A and 6B illustrate results of more detailed calculation of the effect given by the thickness of the DTI side portion 104 to the reflectance of the DTI 20. FIG. 6A illustrates the result of calculation of the reflectance of the DTI 20 when the incidence angle was fixed to 40 degrees (angle close to the real critical angle described above), while the thickness of the DTI side portion 104 was varied. When the incidence angle exceeds 40 degrees, the reflectance of the DTI 20 becomes approximately 100%, and accordingly the calculation was performed herein by fixing the incidence angle to slightly smaller 40 degrees. When the incidence angle is 40 degrees, as the thickness of the DTI side portion 104 increases, the reflectance of the DTI 20 increases to approach 100%.

This can be considered as follows. When the near-infrared light is incident from the silicon 100 on SiO₂ of the DTI side portion 104, 40 degrees as the incidence angle is ideally not less than the critical angle of the total reflection. Accordingly, the near-infrared light is ideally totally reflected by the DTI 20. However, when the thickness of the DTI side portion 104 is not sufficient, a part of the light having leaked into SiO₂ undesirably reaches Cu as an evanescent wave to result in light absorption in Cu. As a result, the reflectance of the DTI 20 is reduced. Meanwhile, as the thickness of the DTI side portion 104 increases, components of the light reaching Cu (the DTI inner portion 103) decrease, and the reflectance of the DTI 20 to the near-infrared light approaches 100%.

As illustrated in FIG. 6A, when the incidence angle is 40 degrees, to adjust the reflectance of the DTI 20 to 95.0% or more, it is appropriate that the thickness of the DTI side portion 104 is 50 nm or more. To adjust the reflectance of the DTI 20 to 98.0% or more, it is appropriate that the thickness of the DTI side portion 104 is 70 nm or more. To adjust the reflectance of the DTI 20 to 99.0% or more, it is appropriate that the thickness of the DTI side portion 104 is 90 nm or more.

To adjust the reflectance of the DTI 20 to 99.5% or more, it is appropriate that the thickness of the DTI side portion 104 is 110 nm or more. To adjust the reflectance of the DTI 20 to 99.7% or more, it is appropriate that the thickness of the DTI side portion 104 is 130 nm or more. To adjust the reflectance of the DTI 20 to 99.8% or more, it is appropriate that the thickness of the DTI side portion 104 is 150 nm or more. To adjust the reflectance of the DTI 20 to 99.9% or more, it is appropriate that the thickness of the DTI side portion 104 is 170 nm or more.

Likewise, FIG. 6B illustrates the result of performing calculation in the same manner as in FIG. 6A, while the incidence angle was fixed to 10 degrees. It is difficult to assume that the incidence angle becomes less than 10 degrees even when the periodic uneven structure portion 101 diffracts the light, and accordingly the calculation was performed by fixing the incidence angle to slightly larger 10 degrees. Since the 10 degrees is not more than the critical angle of the total reflection by the silicon-SiO₂ interface, the total reflection does not occur. Consequently, the near-infrared light reaches Cu as propagation light to be reflected and absorbed by Cu. Then, when the thickness of the DTI side portion 104 varies, the degree of interference of the light varies, and consequently the reflectance of the DTI 20 varies. According to the calculation result in FIG. 6B, when the thickness of the DTI side portion 104 exceeds 200 nm, the reflectance of the DTI 20 begins to decrease.

As illustrated in FIG. 6B, when the incidence angle is 10 degrees, to adjust the reflectance of the DTI 20 to 98.0% or more, it is appropriate that the thickness of the DTI side portion 104 is 190 nm or less. To adjust the reflectance of the DTI 20 to 97.0% or more, it is appropriate that the thickness of the DTI side portion 104 is 240 nm or less. To adjust the reflectance of the DTI 20 to 96.0% or more, it is appropriate that the thickness of the DTI side portion 104 is 260 nm or less. To adjust the reflectance of the DTI 20 to 95.0% or more, it is appropriate that the thickness of the DTI side portion 104 is 270 nm or less.

In the photoelectric conversion device that detects light at a long wavelength such as the near-infrared light (light in the near-infrared region) and converts the light, a pixel size (length of one side of one pixel) is preferably about 5 to 10 In addition, each time the near-infrared light advances by a distance corresponding to the length of the pixel size in the silicon 100, 10% of the near-infrared light is absorbed. In the first embodiment, the near-infrared light advances, while being reflected by the DTI 20, and therefore it can be said that, when the near-infrared light absorbed by the DTI 20 decreases, an advantage offered by causing the DTI 20 to reflect the near-infrared light is satisfactory. For example, after the near-infrared light is reflected by the DTI 20 and before the near-infrared light is reflected again by the DTI 20, the near-infrared light advances by a distance corresponding to at least the pixel size. At this time, 10% of the near-infrared light advancing in the silicon 100 is absorbed by the silicon 100. As a result, when the near-infrared light larger in amount than 10% of the near-infrared light incident on the DTI 20 is absorbed by the DTI 20 at the reflection of the near-infrared light by the DTI 20, the amount of the near-infrared light absorbed by the DTI 20 is larger than the amount of the near-infrared light absorbed by the silicon 100. In this case, it is impossible to ensure a sufficient sensitivity of the photoelectric conversion device to the near-infrared light. Accordingly, the DTI 20 ideally has an absorption rate of 10% or less with respect to the near-infrared light, and more preferably has an absorption rate of 5% or less corresponding to a half of 10% or less. In other words, the reflectance of the DTI 20 is preferably 90% or more, or more preferably 95% or more. Note that the reflectance of the DTI 20 is not limited to 90% or 95% or more. As long as the DTI 20 has a reflectance higher than that of a conventional DTI as illustrated in FIG. 3C, the effects according to the first embodiment can be achieved.

As described above, to increase the reflectance of the DTI 20, when the incidence angle of the light in the near-infrared region is large, the thickness of the DTI side portion 104 is preferably larger. However, when consideration is given also to a case where the incidence angle is small, it is preferable that the thickness of the DTI side portion 104 is not larger than necessary. By thus appropriately setting the film thickness of the DTI side portion 104, it is possible to implement the DTI 20 having both of a high shielding property and a low light absorbing property. Therefore, it is possible to simultaneously improve the sensitivity of the photoelectric conversion device to the light in the near-infrared region and suppress the optical crosstalk.

### Second Embodiment

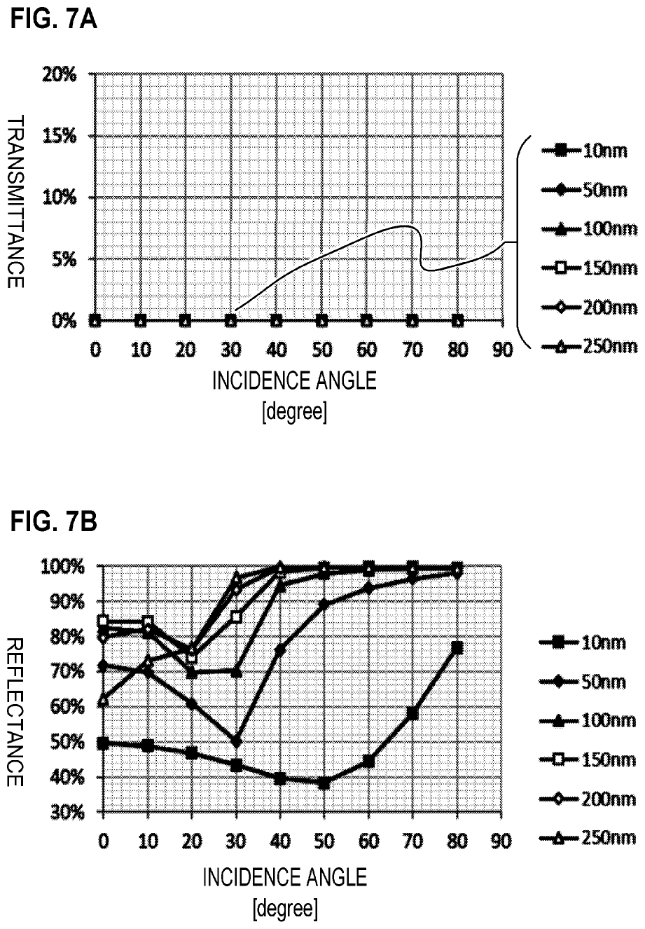

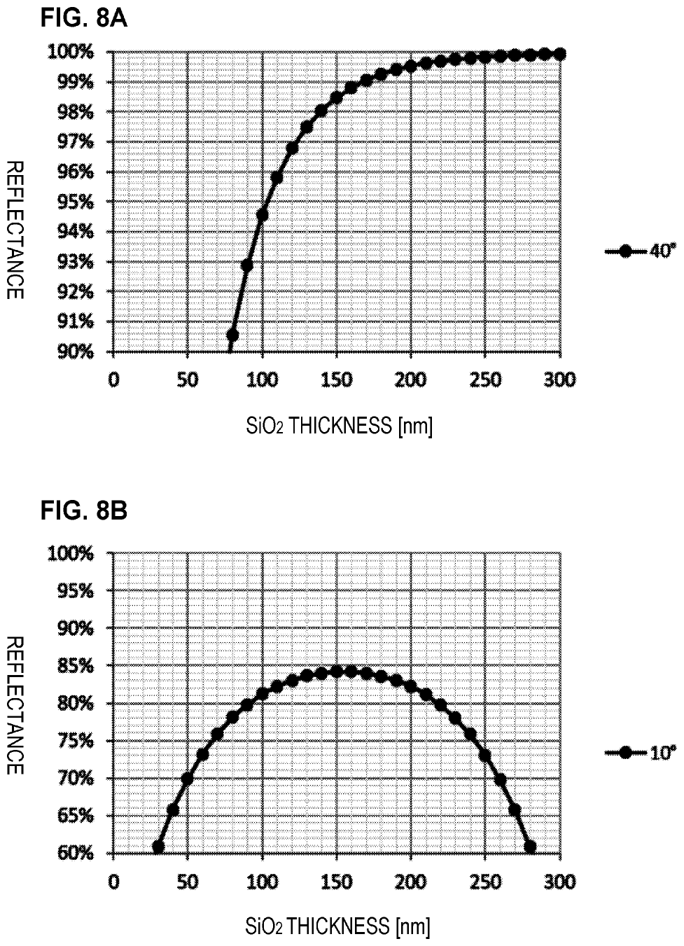

Referring to FIGS. 7A, 7B, 8A, and 8B, an example different from the first embodiment in which the photoelectric conversion device is configured such that the DTI 20 is provided as the pixel separation portion between the pixels will be described. The photoelectric conversion device according to the second embodiment is different from the photoelectric conversion device according to the first embodiment in that the metal material filling the DTI 20 is not Cu, but Co (cobalt), and the configuration is otherwise the same as in the first embodiment.

FIGS. 7A and 7B illustrate results of calculating the transmittance and reflectance of the DTI 20 to the near-infrared light at a wavelength of 940 nm when the thickness of the DTI side portion 104 was varied in the same manner as in the first embodiment. In the same manner as in the first embodiment, the transmittance of the DTI 20 is substantially zero irrespective of the thickness of the DTI side portion 104 and the incidence angle. Meanwhile, the reflectance of the DTI 20 increases at substantially all the incidence angles as the thickness of the DTI side portion 104 increases to 10 nm, 50 nm, and 100 nm. In particular, in a range in which the incidence angle is not less than 40 degrees, as the thickness of the DTI side portion 104 increases, the reflectance of the DTI 20 reaches substantially 100%.

FIGS. 8A and 8B illustrate results of more detailed calculation of the effect given by the thickness of the DTI side portion 104 to the reflectance of the DTI 20 to the near-infrared light. FIG. 8A illustrates the result of the calculation of the reflectance of the DTI 20 according to the thickness of the DTI side portion 104 when the incidence angle was fixed to 40 degrees. Referring to FIG. 8A, in the same manner as in the first embodiment, as the thickness of the DTI side portion 104 increases, the reflectance of the DTI 20 increases to approach 100%. However, it will be understood that, in the second embodiment (in the case of filling with Co), the thickness of the DTI side portion 104 required to reach the same reflectance of the DTI 20 is larger than that in the first embodiment (in the case of filling with Cu). This may be conceivably because, since the light absorption by Co is larger than that by Cu, it is necessary to further reduce the intensity of the evanescent wave reaching the metal material.

When the incidence angle is 40 degrees, to adjust the reflectance of the DTI 20 to 95.0% or more, it is appropriate that the thickness of the DTI side portion 104 is 110 nm or more. To adjust the reflectance of the DTI 20 to 98.0% or more, it is appropriate that the thickness of the DTI side portion 104 is 140 nm or more. To adjust the reflectance of the DTI 20 to 99.0% or more, it is appropriate that the thickness of the DTI side portion 104 is 170 nm or more.

To adjust the reflectance of the DTI 20 to 99.5% or more, it is appropriate that the thickness of the DTI side portion 104 is 200 nm or more. To adjust the reflectance of the DTI 20 to 99.7% or more, it is appropriate that the thickness of the DTI side portion 104 is 220 nm or more. To adjust the reflectance of the DTI 20 to 99.8% or more, it is appropriate that the thickness of the DTI side portion 104 is 240 nm or more. To adjust the reflectance of the DTI 20 to 99.9% or more, it is appropriate that the thickness of the DTI side portion 104 is 270 nm or more.

Likewise, FIG. 8B illustrates the result of performing calculation in the same manner as in FIG. 8A, while the incidence angle was fixed to 10 degrees. In the calculation result in FIG. 8B, when the thickness of the DTI side portion 104 is in the vicinity of 150 nm, the reflectance of the DTI 20 reaches a peak.

When the incidence angle is 10 degrees, to adjust the reflectance of the DTI 20 to 80.0% or more, it is appropriate that the thickness of the DTI side portion 104 is 210 nm or less. To adjust the reflectance of the DTI 20 to 75.0% or more, it is appropriate that the thickness of the DTI side portion 104 is 240 nm or less. To adjust the reflectance of the DTI 20 to 70.0% or more, it is appropriate that the thickness of the DTI side portion 104 is 250 nm or less. To adjust the reflectance of the DTI 20 to 65.0% or more, it is appropriate that the thickness of the DTI side portion 104 is 270 nm or less. Note that, when the reflectance of the DTI 20 is 65.0% or more, it is possible to achieve a reflectance which is 10% or more higher than the reflectance of the DTI filled with Co described with reference to FIG. 3C. Therefore, the photosensitive conversion device according to the second embodiment can have the sensitivity to the light which is sufficiently higher than that of the photosensitive conversion device described with reference to FIG. 3C.

### Third Embodiment

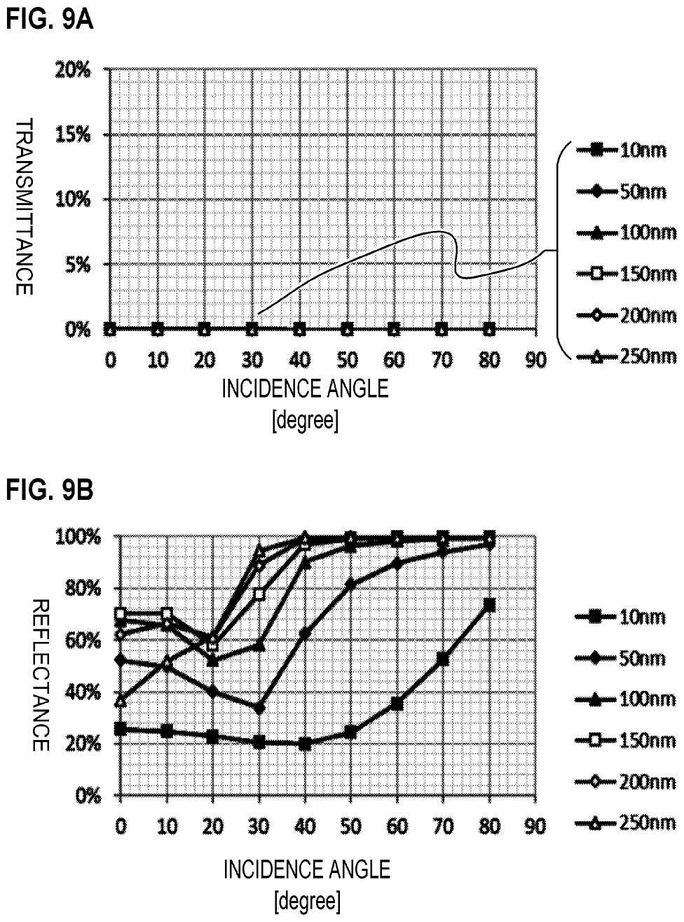

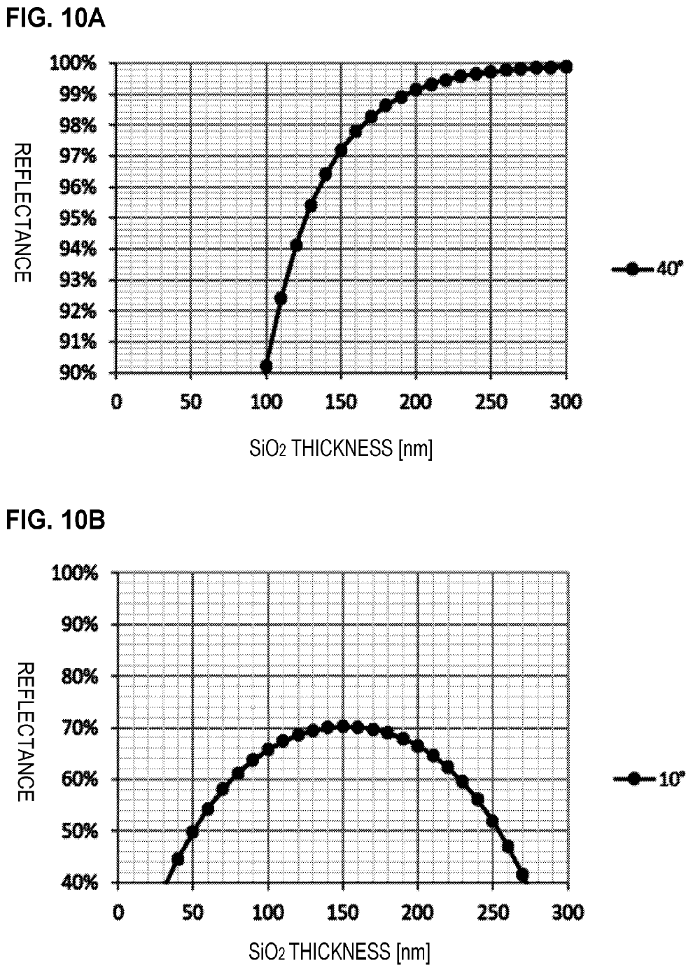

Referring to FIGS. 9A, 9B, 10A, and 10B, an example different from the first and second embodiments in each of which the photoelectric conversion device is configured such that the DTI 20 is provided as the pixel separation portion between the pixels will be described. The photoelectric conversion device according to the third embodiment is different from the photoelectric conversion device according to the first embodiment in that the metal material filling the DTI 20 is not Cu, but W (tungsten), and the configuration is otherwise the same as in the first embodiment.

FIGS. 9A and 9B illustrate results of calculating the transmittance and reflectance of the DTI 20 to the near-infrared light at a wavelength of 940 nm when the thickness of the DTI side portion 104 was varied in the same manner as in the first embodiment. In the third embodiment also, in the same manner as in the first embodiment, the transmittance of the DTI 20 is substantially zero irrespective of the thickness of the DTI side portion 104 and the incidence angle. The reflectance of the DTI 20 increases at substantially all the incidence angles as the thickness of the DTI side portion 104 increases to 10 nm, 50 nm, and 100 nm. In particular, in the range in which the incidence angle is not less than 40 degrees, as the thickness of the DTI side portion 104 increases, the reflectance of the DTI 20 to the near-infrared light reaches substantially 100%.

FIGS. 10A and 10B illustrate results of more detailed calculation of the effect given by the thickness of the DTI side portion 104 to the reflectance of the DTI 20 to the near-infrared light. FIG. 10A illustrates the result of the calculation of the reflectance of the DTI 20 according to the thickness of the DTI side portion 104 when the incidence angle was fixed to 40 degrees. Referring to FIG. 10A, in the same manner as in the first embodiment, as the thickness of the DTI side portion 104 increases, the reflectance of the DTI 20 increases to approach 100%.

However, it will be understood that, in a case of filling with W in the third embodiment, the thickness of the DTI side portion 104 required by the reflectance of the DTI 20 to reach the same value is larger than that in the first embodiment (in the case of filling with Cu) and that in the second embodiment (in the case of filling with Co). This may be conceivably because, since the light absorption by W is larger than that by Cu and that by Co, it is necessary to further reduce the intensity of the evanescent wave reaching the metal material.

When the incidence angle is 40 degrees, to adjust the reflectance of the DTI 20 to 95.0% or more, it is appropriate that the thickness of the DTI side portion 104 is 130 nm or more. To adjust the reflectance of the DTI 20 to 98.0% or more, it is appropriate that the thickness of the DTI side portion 104 is 170 nm or more. To adjust the reflectance of the DTI 20 to 99.0% or more, it is appropriate that the thickness of the DTI side portion 104 is 200 nm or more.

To adjust the reflectance of the DTI 20 to 99.5% or more, it is appropriate that the thickness of the DTI side portion 104 is 220 nm or more. To adjust the reflectance of the DTI 20 to 99.7% or more, it is appropriate that the thickness of the DTI side portion 104 is 240 nm or more. To adjust the reflectance of the DTI 20 to 99.8% or more, it is appropriate that the thickness of the DTI side portion 104 is 260 nm or more. To adjust the reflectance of the DTI 20 to 99.9% or more, it is appropriate that the thickness of the DTI side portion 104 is 290 nm or more.

Likewise, FIG. 10B illustrates the result of performing calculation in the same manner as in FIG. 10A, while the incidence angle was fixed to 10 degrees. In the calculation result in FIG. 10B, when the thickness of the DTI side portion 104 is in the vicinity of 150 nm, the reflectance of the DTI 20 reaches the peak.

When the incidence angle is 10 degrees, to adjust the reflectance of the DTI 20 to 65.0% or more, it is appropriate that the thickness of the DTI side portion 104 is 200 nm or less. To adjust the reflectance of the DTI 20 to 60.0% or more, it is appropriate that the thickness of the DTI side portion 104 is 220 nm or less. To adjust the reflectance of the DTI 20 to 55.0% or more, it is appropriate that the thickness of the DTI side portion 104 is 240 nm or less. To adjust the reflectance of the DTI 20 to 50.0% or more, it is appropriate that the thickness of the DTI side portion 104 is 250 nm or less. Note that, when the reflectance of the DTI 20 is 50.0% or more, it is possible to achieve a reflectance which is 20% or more higher than the reflectance of the DTI filled with W described with reference to FIG. 3C. Therefore, the photosensitive conversion device according to the third embodiment can have the sensitivity to the light which is sufficiently higher than that of the photosensitive conversion device described with reference to FIG. 3C.

### Fourth Embodiment

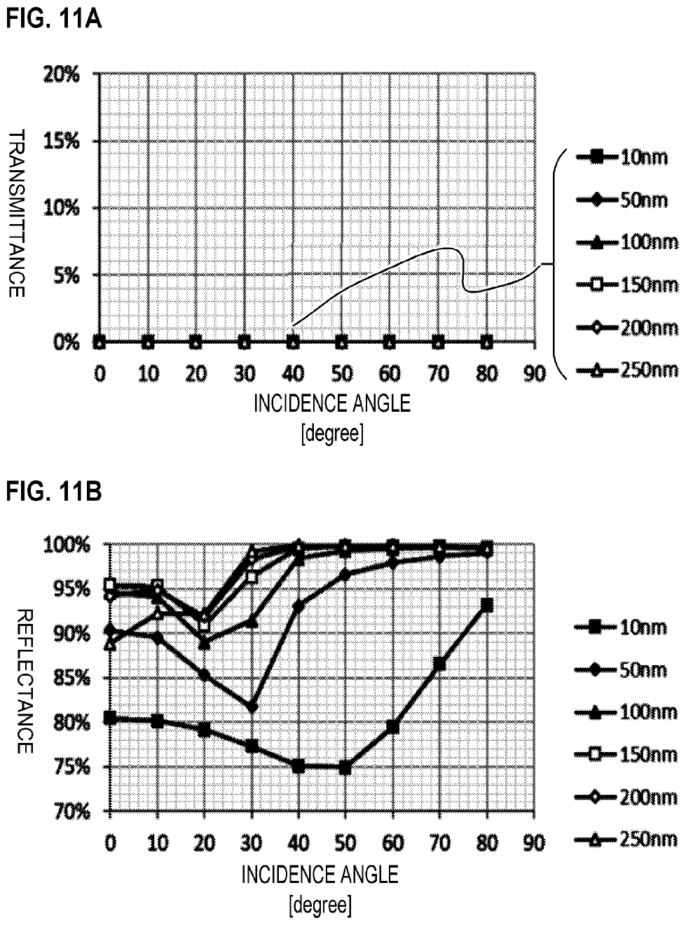

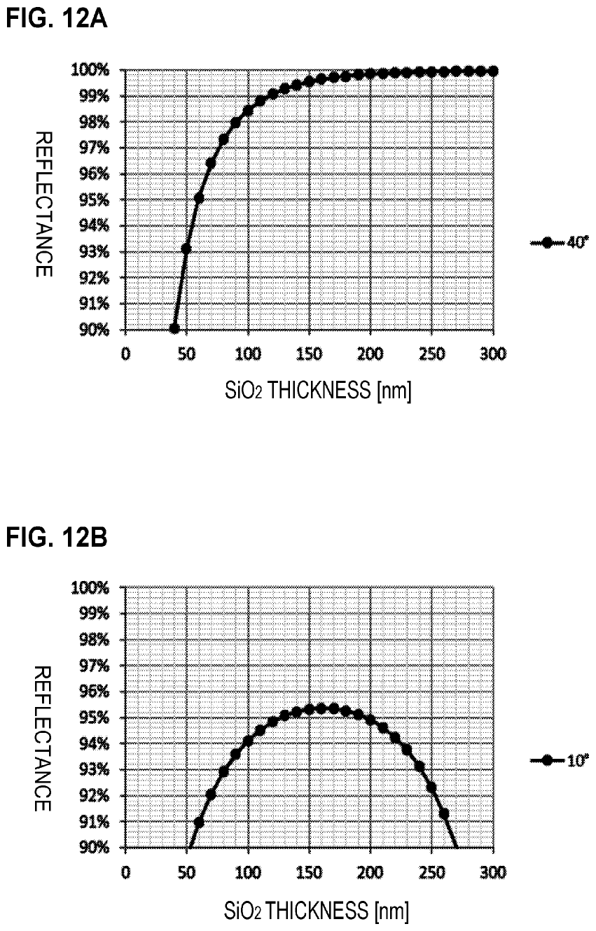

Referring to FIGS. 11A, 11B, 12A, and 12B, an example different from the first to third embodiments in each of which the photoelectric conversion device is configured such that the DTI 20 is provided as the pixel separation portion between the pixels. The photoelectric conversion device according to the fourth embodiment is different from the photoelectric conversion device according to the first embodiment in that the metal material filling the DTI 20 is not Cu, but Al (aluminum), and the configuration is otherwise the same as in the first embodiment.

FIGS. 11A and 11B illustrate results of calculating the transmittance and reflectance of the DTI 20 to the near-infrared light at a wavelength of 940 nm when the thickness of the DTI side portion 104 was varied in the same manner as in the first embodiment. In the fourth embodiment also, in the same manner as in the first embodiment, the transmittance of the DTI 20 to the near-infrared light is substantially zero irrespective of the thickness of the DTI side portion 104 and the incidence angle. The reflectance of the DTI 20 to the near-infrared light increases at substantially all the incidence angles as the thickness of the DTI side portion 104 increases to 10 nm, 50 nm, and 100 nm. In particular, in the range in which the incidence angle is not less than 40 degrees, as the thickness of the DTI side portion 104 increases, the reflectance of the DTI 20 to the near-infrared light reaches substantially 100%.

FIGS. 12A and 12B illustrate results of more detailed calculation of the effect given by the thickness of the DTI side portion 104 to the reflectance of the DTI 20 to the near-infrared light. FIG. 12A illustrates the result of the calculation of the reflectance of the DTI 20 according to the thickness of the DTI side portion 104 when the incidence angle was fixed to 40 degrees. Referring to FIG. 12A, in the same manner as in the first embodiment, as the thickness of the DTI side portion 104 increases, the reflectance of the DTI 20 increases to approach 100%. However, it will be understood that, in the fourth embodiment (in the case of filling with Al), the thickness of the DTI side portion 104 required to reach the same reflectance is larger than that in the first embodiment (in the case of filling with Cu). Meanwhile, in the fourth embodiment, the thickness of the DTI side portion 104 required to reflect the same amount of light is smaller than that in the second embodiment (in the case of filling with Co) and that in the third embodiment (in the case of filling with W).

When the incidence angle is 40 degrees, to adjust the reflectance of the DTI 20 to 95.0% or more, it is appropriate that the thickness of the DTI side portion 104 is 60 nm or more. To adjust the reflectance of the DTI 20 to 98.0% or more, it is appropriate that the thickness of the DTI side portion 104 is 90 nm or more. To adjust the reflectance of the DTI 20 to 99.0% or more, it is appropriate that the thickness of the DTI side portion 104 is 120 nm or more.

To adjust the reflectance of the DTI 20 to 99.5% or more, it is appropriate that the thickness of the DTI side portion 104 is 150 nm or more. To adjust the reflectance of the DTI 20 to 99.7% or more, it is appropriate that the thickness of the DTI side portion 104 is 170 nm or more. To adjust the reflectance of the DTI 20 to 99.8% or more, it is appropriate that the thickness of the DTI side portion 104 is 180 nm or more. To adjust the reflectance of the DTI 20 to 99.9% or more, it is appropriate that the thickness of the DTI side portion 104 is 210 nm or more.

Likewise, FIG. 12B illustrates the result of performing calculation in the same manner as in FIG. 12A, while the incidence angle was fixed to 10 degrees. In the calculation result in FIG. 12B, when the thickness of the DTI side portion 104 is in the vicinity of 150 nm, the reflectance of the DTI 20 reaches the peak.

When the incidence angle is 10 degrees, to adjust the reflectance of the DTI 20 to 95.0% or more, it is appropriate that the thickness of the DTI side portion 104 is 190 nm or less. To adjust the reflectance of the DTI 20 to 94.0% or more, it is appropriate that the thickness of the DTI side portion 104 is 220 nm or less. To adjust the reflectance of the DTI 20 to 93.0% or more, it is appropriate that the thickness of the DTI side portion 104 is 240 nm or less. To adjust the reflectance of the DTI 20 to 92.0% or more, it is appropriate that the thickness of the DTI side portion 104 is 250 nm or less. Note that, when the reflectance of the DTI 20 is 92.0% or more, it is possible to achieve a reflectance which is 10% or more higher than the reflectance of the DTI filled with Al described with reference to FIG. 3C. Therefore, the photosensitive conversion device according to the fourth embodiment can have the sensitivity to the light which is sufficiently higher than that of the photosensitive conversion device described with reference to FIG. 3C.

Thus, according to the first to fourth embodiments described above, it is possible to implement the DTI 20 having the reflectance higher than that of the conventional metal-filled DTI, while adjusting the transmittance of the DTI 20 to substantially zero.

Note that, even when the DTI inner portion 103 is filled with any of the metal materials described above, the reflectance of the DTI 20 is higher in most cases when the incidence angle is 40 degrees than when the incidence angle is 10 degrees without greatly depending on the thickness of the DTI side portion 104. Accordingly, the thickness of the DTI side portion 104 may also have a value (approximately 150 nm) which allows the reflectance of the DTI 20 to the near-infrared light to reach the peak when the incidence angle is 10 degrees irrespective of the filling metal material.

### Fifth Embodiment

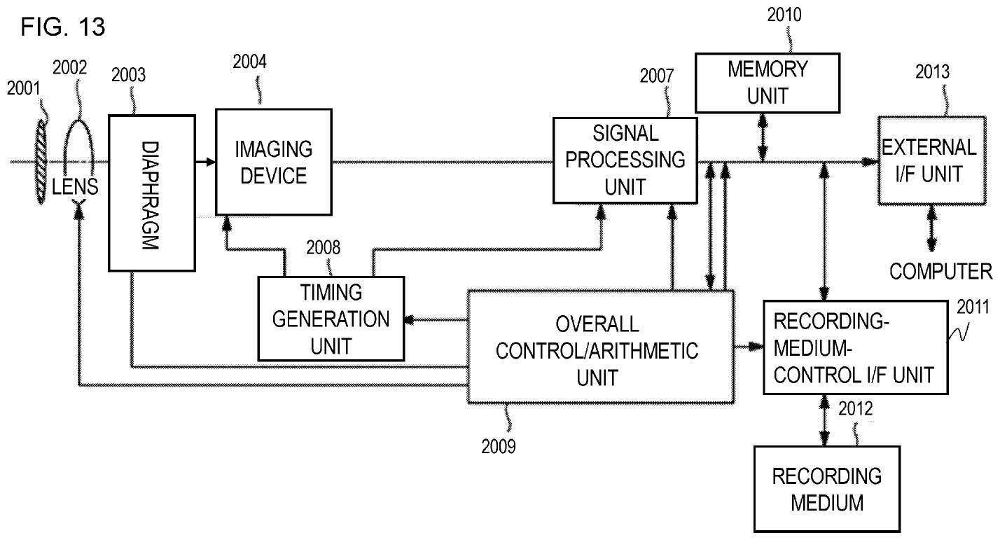

Referring to FIG. 13, a description will be given of a photoelectric conversion system according to the fifth embodiment. FIG. 13 is a block diagram illustrating a schematic configuration of the photoelectric conversion system according to the fifth embodiment.

The photoelectric conversion device (imaging device) described in each of the foregoing embodiments is applicable to various photoelectric conversion systems. Examples of the photoelectric conversion systems to which the photoelectric conversion device is applicable include a digital still camera, a digital camcorder, a monitoring camera, a copier, a fax, a mobile phone, an in-vehicle camera, and an observation satellite. In addition, a camera module including an optical system such as a lens and the imaging device is also included in the photoelectric conversion systems. By way of example, FIG. 13 illustrates a block diagram of the digital still camera as an example of the photoelectric conversion systems.

The photoelectric conversion system illustrated by way of example in FIG. 13 includes an imaging device 2004 as an example of the photoelectric conversion device and a lens 2002 that causes the imaging device 2004 to form an image of an optical image of a subject to be imaged. The photoelectric conversion system includes a diaphragm 2003 for varying an amount of light passing through the lens 2002 and a barrier 2001 for protecting the lens 2002. The lens 2002 and the diaphragm 2003 are in an optical system that focuses light onto the imaging device 2004. The imaging device 2004 is the photoelectric conversion device (imaging device) in any of the embodiments described above, and converts the optical image formed by the lens 2002 to an electric signal.

The photoelectric conversion system also includes a signal processing unit 2007 (signal processing device) serving as an image generation unit that performs processing of an output signal output from the imaging device 2004 to generate an image. The signal processing unit 2007 performs an operation of performing various correction and compression as necessary to output the image data. The signal processing unit 2007 may be formed on a semiconductor substrate provided with the imaging device 2004, or may also be formed on another substrate other than that formed with the imaging device 2004. Alternatively, the imaging device 2004 and the signal processing unit 2007 may also be formed on the same semiconductor substrate.

The photoelectric conversion system further includes a memory unit 2010 for temporarily storing the image data and an external interface unit (external I/F unit) 2013 for performing communication with an external computer or the like. The photoelectric conversion system further includes a recording medium 2012 for performing recording or reading of imaging data such as a semiconductor memory and a recording-medium-control interface unit (recording-medium-control I/F unit) 2011 for performing recording or reading to the recording medium 2012. Note that the recording medium 2012 may be embedded in the photoelectric conversion system or may also be detachable therefrom.

The photoelectric conversion system further includes an overall control/arithmetic unit 2009 that controls various arithmetic operations and the entire digital still camera and a timing generation unit 2008 that outputs various timing signals to the imaging device 2004 and to the signal processing unit 2007. The timing signals or the like may also be input from the outside, and the photoelectric conversion system may appropriately include at least the imaging device 2004 and the signal processing unit 2007 that processes the output signal output from the imaging device 2004.

The imaging device 2004 outputs an imaging signal to the signal processing unit 2007. The signal processing unit 2007 performs predetermined signal processing on the imaging signal output from the imaging device 2004 and outputs the image data. The signal processing unit 2007 uses the imaging signal to generate an image.

Thus, according to the fifth embodiment, it is possible to implement the photoelectric conversion system to which the photoelectric conversion device (imaging device) in any of the embodiments described above is applied.

### Sixth Embodiment

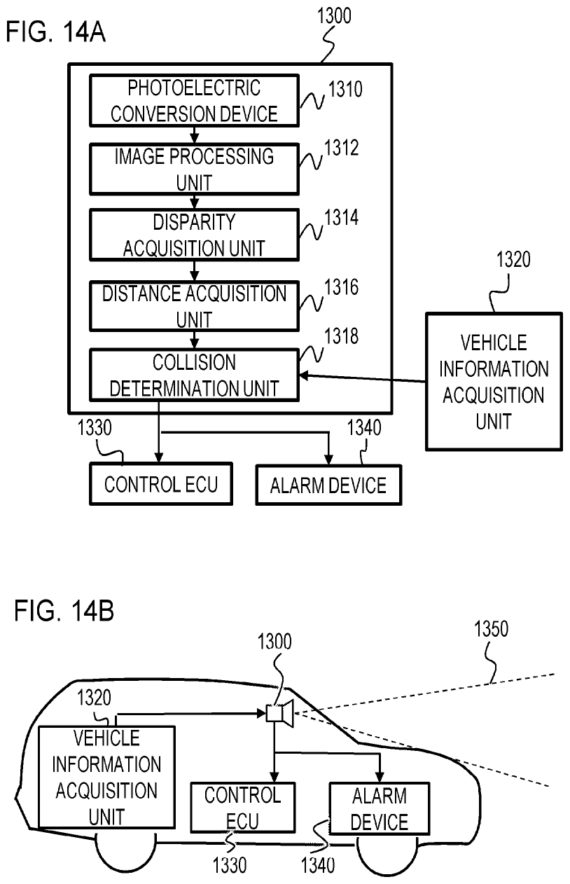

Referring to FIGS. 14A and 14B, a description will be given of a photoelectric conversion system and a moving body in the sixth embodiment. FIGS. 14A and 14B are diagrams illustrating a configuration of the photoelectric conversion system and the moving body in the sixth embodiment.

FIG. 14A illustrates an example of a photoelectric conversion system related to an in-vehicle camera. A photoelectric conversion system 1300 includes an imaging device 1310. The imaging device 1310 is the photoelectric conversion device (imaging device) described in any of the foregoing embodiments. The photoelectric conversion system 1300 includes an image processing unit 1312 that performs image processing on a plurality of image data sets acquired by the imaging device 1310. The photoelectric conversion system 1300 also includes a disparity acquisition unit 1314 that calculates a disparity (a phase difference between disparity images) from the plurality of image data sets acquired by the photoelectric conversion system 1300. The photoelectric conversion system 1300 also includes a distance acquisition unit 1316 that calculates a distance to a subject to be imaged on the basis of the calculated disparity and a collision determination unit 1318 that determines whether or not there is a possibility of a collision on the basis of the calculated distance. Each of the disparity acquisition unit 1314 and the distance acquisition unit 1316 mentioned herein is an example of a distance information acquisition means that acquires distance information sets each representing the distance to the subject. In other words, the distance information sets are information related to the disparity, an amount of defocusing, the distance to the subject, and the like. The collision determination unit 1318 may also use any of these distance information sets to determine the possibility of a collision. The distance information acquisition means may also be implemented by dedicatedly designed hardware or by a software module. Alternatively, the distance information acquisition means may also be implemented by a FPGA (Field Programmable Gate Array), an ASIC (Application Specific Integrated Circuit), or the like or by a combination thereof.

The photoelectric conversion system 1300 is connected to a vehicle information acquisition device 1320 to be able to acquire vehicle information such as a vehicle speed, a yaw rate, and a steering angle. The photoelectric conversion system 1300 is also connected to a control ECU 1330 serving as a control device (control unit) that outputs a control signal for generating a braking force on a vehicle on the basis of a result of the determination by the collision determination unit 1318. The photoelectric conversion system 1300 is also connected to an alarm device 1340 that generates an alarm to a driver on the basis of the result of the determination by the collision determination unit 1318. For example, when the possibility of a collision is high as a result of the determination by the collision determination unit 1318, the control ECU 1330 performs vehicle control to avoid a collision or reduce damage by braking, easing off an accelerator pedal, or reducing an engine output. The alarm device 1340 warns a user through generation of an alarm such as a sound, displaying of alarm information on a screen of a car navigation system or the like, giving of vibration to a seat belt or a steering wheel, or the like.

In the sixth embodiment, the photoelectric conversion system 1300 images a scene around the vehicle, e.g., a scene ahead of or behind the vehicle. FIG. 14B illustrates the photoelectric conversion system when the scene ahead of the vehicle (an imaging range 1350) is imaged. The vehicle information acquisition device 1320 transmits an instruction to the photoelectric conversion system 1300 or to the imaging device 1310. Such a configuration can further improve accuracy of distance measurement.

The foregoing has described the example in which the photoelectric conversion system performs control so as to prevent a collision with another vehicle. However, the photoelectric conversion system is also applicable to control of causing a host vehicle to perform automated driving following another vehicle, control of causing the host vehicle to perform automated driving so as not to drift from a lane, or the like. In addition, applications of the photoelectric conversion system are not limited to a vehicle such as the host vehicle. For example, the photoelectric conversion system is also applicable to a moving body (transportation device) such as, e.g., a vessel, an aircraft, an industrial robot, or the like. Moreover, the applications of the photoelectric conversion system are not limited to the moving bodies, and the photoelectric conversion system is also widely applicable to a device using object recognition such as an intelligent transportation system (ITS).

### Modified Embodiments

The present invention are not limited to the embodiments described above, and can variously be modified. For instance, an example in which a configuration of a part of any embodiment is added to another embodiment and an example in which a configuration of a part of any embodiment is substituted by a configuration of a part of another embodiment are also included in the embodiments of the present invention.

The photoelectric conversion system shown in each of the fifth and sixth embodiments shows an example of the photoelectric conversion system to which the photoelectric conversion device is applicable, and the photoelectric conversion system to which the photoelectric conversion device of the present invention is applicable is not limited to configurations illustrated in FIGS. 13, 14A, and 14B.

### Seventh Embodiment: ToF System

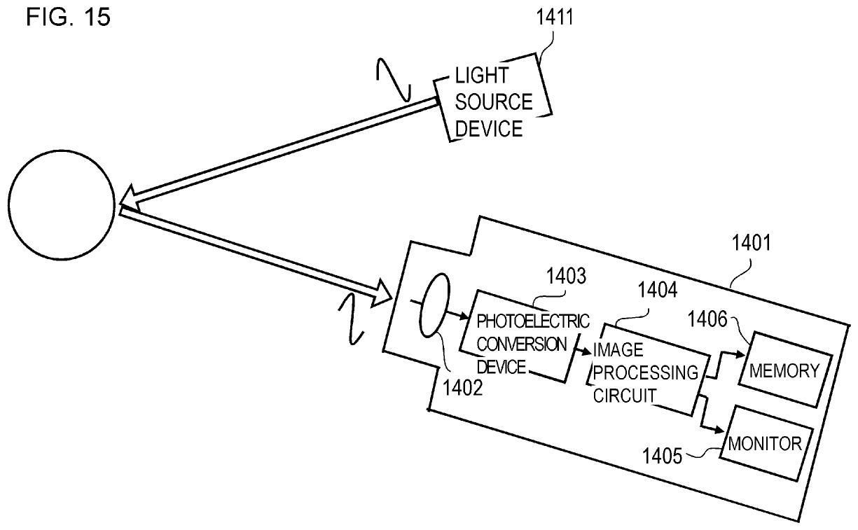

Referring to FIG. 15, a description will be given of a photoelectric conversion system in the seventh embodiment. FIG. 15 is a block diagram illustrating an example of a configuration of a distance image sensor serving as a photoelectric conversion system in the seventh embodiment.

As illustrated in FIG. 15, a distance image sensor 1401 is configured to include an optical system 1402, a photoelectric conversion device 1403, an image processing circuit 1404, a monitor 1405, and a memory 1406. The distance image sensor 1401 receives light (modulated light or pulsed light) projected from a light source device 1411 toward a subject to be imaged and reflected from a surface of the subject to be able to acquire a distance image based on a distance to the subject.

The optical system 1402 is configured to include one or a plurality of lenses to guide image light (incident light) from the subject to the photoelectric conversion device 1403 and form an image on a light receiving surface (sensor unit) of the photoelectric conversion device 1403.

To the photoelectric conversion device 1403, the photoelectric conversion device in each of the embodiments described above is applied, and a distance signal representing a distance determined from a light reception signal output from the photoelectric conversion device 1403 is supplied to the image processing circuit 1404.

The image processing circuit 1404 performs, on the basis of the distance signal supplied from the photoelectric conversion device 1403, image processing of building a distance image. Then, the distance image (image data) obtained by the image processing is supplied to the monitor 1405 to be displayed thereon or supplied to the memory 1406 to be stored (recorded) therein.

By applying the photoelectric conversion device described above to the distance image sensor 1401 thus configured, as a result of an improved pixel property, it is possible to, e.g., acquire a more precise distance image.

### Eighth Embodiment: Endoscope

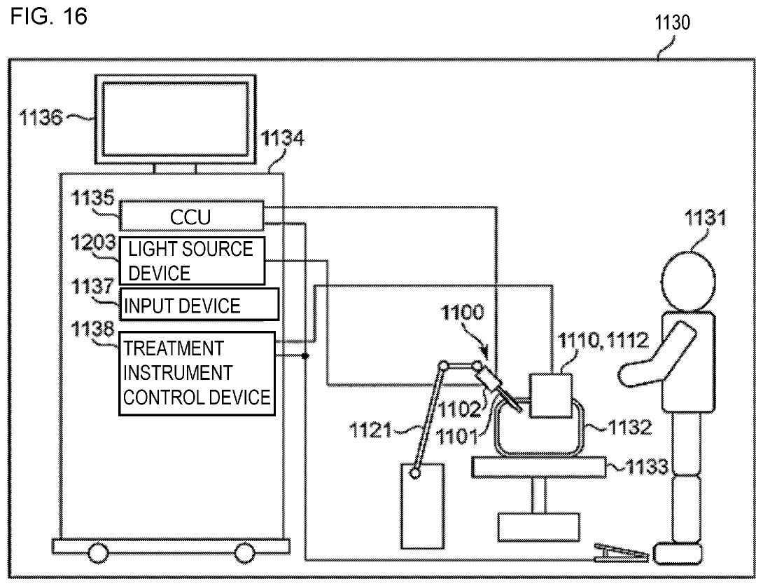

Referring to FIG. 16, a description will be given of a photoelectric conversion system in the eighth embodiment. FIG. 16 is a diagram illustrating an example of a schematic configuration of an endoscopic surgical system serving as the photoelectric conversion system in the eighth embodiment.

FIG. 16 illustrates surgery being performed by an operator (doctor) 1131 on a patient 1132 on a patient bed 1133 by using an endoscopic surgical system 1030. As illustrated, the endoscopic surgical system 1030 includes an endoscope 1100, a surgical instrument 1110, and a cart 1134 on which various devices for the endoscopic surgery are mounted.

The endoscope 1100 includes a lens barrel 1101 having a region of a predetermined distance from a leading end which is to be inserted into a body cavity of the patient 1132 and a camera head 1102 connected to a proximal end of the lens barrel 1101. In the illustrated example, the endoscope 1100 configured as a so-called rigid scope having the rigid lens barrel 1101 is illustrated, but the endoscope 1100 may also be configured as a so-called flexible scope having a flexible lens barrel.

In the leading end of the lens barrel 1101, an opening in which an objective lens is fitted is provided. To the endoscope 1100, a light source device 1203 is connected, and light generated from the light source device 1203 is guided by a light guide provided to extend in the lens barrel 1101 to the leading end of the lens barrel to be applied to an observation object in the body cavity of the patient 1132 via the objective lens. Note that the endoscope 1100 may be a forward-viewing endoscope, a forward-oblique viewing endoscope, or a side-viewing endoscope.

In the camera head 1102, an optical system and a photoelectric conversion device are provided, and the reflected light (observation light) from the observation object is focused by the optical system onto the photoelectric conversion device. The observation light is photoelectrically converted by the photoelectric conversion device, and an electric signal corresponding to the observation light, i.e., an image signal corresponding to an observation image is generated. As the photoelectric conversion device, the photoelectric conversion device (imaging device) described in each of the embodiments described above can be used. The image signal is transmitted as RAW data to a CCU (Camera Control Unit) 1135.

The CCU 1135 is formed of a CPU (Central Processing Unit), a GPU (Graphics Processing Unit), or the like to comprehensively control operations of the endoscope 1100 and a display device 1136. The CCU 1135 further receives the image signal from the camera head 1102 and performs, on the image signal, various image processing for displaying an image based on the image signal such as, e.g., development processing (demosaic processing).

The display device 1136 displays, under control of the CCU 1135, an image based on the image signal subjected to the image processing performed by the CCU 1135.

The light source device 1203 is formed of a light source such as, e.g., an LED (Light Emitting Diode) to supply, to the endoscope 1100, illumination light when a region to be operated or the like is to be photographed.

An input device 1137 is an input interface with respect to the endoscopic surgical system 1030. The user can input various information and instructions to the endoscopic surgical system 1030 via the input device 1137.

A treatment instrument control device 1138 controls driving of an energy treatment instrument 1112 for tissue ablation, incision, blood vessel sealing, or the like.

The light source device 1203 that supplies the illumination light to the endoscope 1100 when the region to be operated is to be photographed can be formed of a white light source including, e.g., an LED, a laser light source, or a combination thereof. When the white light source includes a combination of RGB laser light sources, an output intensity and output timing of each of colors (each of wavelengths) can be controlled with high precision, and therefore it is possible to adjust a white balance of a captured image in the light source device 1203. In this case, by illuminating the observation object with laser light from each of the RGB laser light sources by time division and controlling driving of an imaging element of the camera head 1102 in synchronization with timing of the illumination, it is also possible to capture images corresponding to RGB by time division. This method allows a color image to be obtained even though the imaging element is not provided with color filters.

It may also be possible to control driving of the light source device 1203 such that an intensity of light to be output is changed at predetermined time intervals. By controlling the driving of the imaging element of the camera head 1102 in synchronization with timing of the changing of the light intensity to acquire images by time division and synthesizing the images, it is possible to generate a high-dynamic-range image without so-called blocked-up shadows and blown-out highlights.

The light source device 1203 may also be configured to be able to supply light in a predetermined wavelength band corresponding to special light observation. In the special light observation, e.g., wavelength dependency of light absorption in a body tissue is used. Specifically, by applying light in a band narrower than that of the illumination light (i.e., white light) during normal observation, a predetermined tissue such as a blood vessel in a superficial portion of a mucous membrane is photographed with a high contrast. Alternatively, in the special light observation, fluorescent observation may also be performed in which an image is obtained with fluorescent light generated by applying excitation light. In the fluorescent observation, it is possible to perform illumination of the body tissue with the excitation light and observation of the fluorescent light from the body tissue, local injection of a test agent such as indocyanine green (ICG) into the body tissue, illumination of the body tissue with the excitation light corresponding to a fluorescence wavelength of the test agent, and obtention of a fluorescent image, or the like. The light source device 1203 may be configured to be able to supply the narrow-band light and/or the excitation light corresponding to such special light observation.

### Ninth Embodiment: Smart Glasses

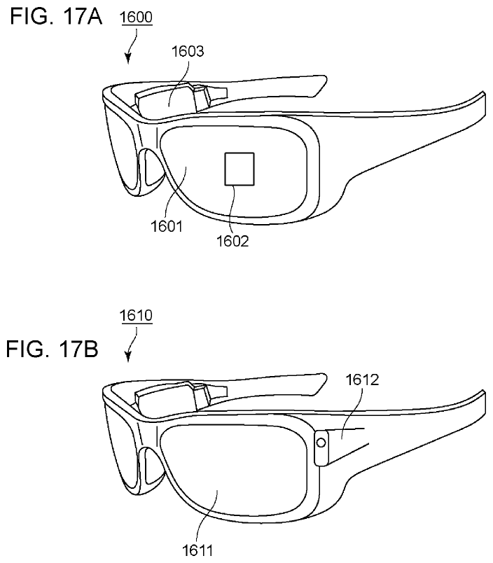

Referring to FIGS. 17A and 17B, a description will be given of a photoelectric conversion system in the ninth embodiment. FIG. 17A illustrates eyeglasses 1600 (smart glasses) serving as a photoelectric conversion system in the ninth embodiment. The eyeglasses 1600 include a photoelectric conversion device 1602. The photoelectric conversion device 1602 is the photoelectric conversion device (imaging device) described in each of the foregoing embodiments. On a back side of a lens 1601, a display device including a light emitting device such as an OLED or an LED may also be provided. The photoelectric conversion device 1602 may be one or include the plurality of photoelectric conversion devices. It may also be possible to use a combination of a plurality of types of photoelectric conversion devices. A position at which the photoelectric conversion device 1602 is disposed is not limited to that in FIG. 17A.

The eyeglasses 1600 further include a control device 1603. The control device 1603 functions as a power source that supplies electric power to the photoelectric conversion device 1602 and to the display device described above. The control device 1603 controls operations of the photoelectric conversion device 1602 and the display device. The lens 1601 is formed with an optical system for focusing light onto the photoelectric conversion device 1602.

FIG. 17B illustrates eyeglasses 1610 (smart glasses) according to an application example. The eyeglasses 1610 include a control device 1612. In the control device 1612, a photoelectric conversion device corresponding to the photoelectric conversion device 1602 and a display device are mounted. In a lens 1611, the photoelectric conversion device in the control device 1612 and an optical system for projecting emitted light from the display device are formed and, onto the lens 1611, an image is projected. The control device 1612 functions as a power source for supplying electric power to the photoelectric conversion device and to the display device, and also controls operations of the photoelectric conversion device and the display device. The control device may also include a line-of-sight sensing unit that senses a line of sight from an eyeglass wearer. For the sensing of the line of sight, an infrared ray may be used. An infrared light emitting unit emits infrared light to eyeballs of the user watching a displayed image. Through detection of the infrared light emitted and reflected from the eyeballs by an imaging unit including a light receiving element, captured images of the eyeballs are obtained. By having a reduction means that reduces the light from the infrared light emitting unit to the display unit in plan view, degradation of an image quality is reduced.

From the captured images of the eyeballs obtained through imaging using the infrared light, the line of sight of the user with respect to the displayed image is detected. To the line-of-sight detection using the captured images of the eyeballs, any known method is applicable. By way of example, a line-of-sight detection method based on Purkinje images resulting from reflection of illumination light by corneas can be used.

More specifically, line-of-sight detection processing based on a pupil cornea reflection method is performed. Line-of-sight vectors representing directions of the eyeballs (rotation angles) are calculated on the basis of the images of the corneas and the Purkinje images each included in the captured images of the eyeballs to allow the line-of-sight of the user to be detected.

The display device in the ninth embodiment may include the photoelectric conversion device including the light receiving element and control the image displayed on the display device on the basis of line-of-sight information of the user from the photoelectric conversion device.

Specifically, the display device determines, on the basis of the line-of-sight information, a first field-of-view region watched by the user and a second field-of-view region other than the first field-of-view region. The first field-of-view region and the second field-of-view region may be determined by the control device of the display device, or may also be regions determined by an external control device and received by the display device. In a display region of the display device, a display resolution in the first field-of-view region may be controlled to be higher than a display resolution in the second field-of-view region. In other words, the resolution in the second field-of-view region may be set lower than that in the first field-of-view region.

Alternatively, the display region may also include a first display region and a second display region other than the first display region, and a region with a higher priority may be determined from between the first display region and the second display region. The first field-of-view region and the second field-of-view region may be determined by the control device of the display device, or may also be regions determined by the external control device and received by the display device. The resolution in the region with the higher priority may also be controlled to be higher than the resolution in the region other than the region with the higher priority. In other words, the resolution in the region with a relatively low priority may be set low.

Note that, for the determination of the first field-of-view region and the region with the higher priority, AI may also be used. The AI may be a model configured to estimate an angle of a line of sight from the images of the eyeballs and a distance to a target object ahead of the line of sight by using, as teacher data, the images of the eyeballs and directions in which the eyeballs of the image were actually viewing. It may be possible that the display device, the photoelectric conversion device, or an external device has an AI program. When the external device has the AI program, the AI program is transmitted by communication to the display device.

When the display control is performed on the basis of visual recognition sensing, the ninth embodiment is favorably applicable to smart glasses further including a photoelectric conversion device that images the outside. The smart glasses can display information on the imaged outside in real time.

According to the foregoing, it is possible to simultaneously improve the sensitivity of the photoelectric conversion device to the light in the near-infrared region and suppress optical crosstalk.

The embodiments described above show only specific examples for implementing the present invention, and should not be construed as limiting the technical scope of the present invention. In other words, the present invention can be implemented in various forms without departing from the technical idea or major features of the invention.

### Other Embodiments

Embodiment(s) of the present invention can also be realized by a computer of a system or apparatus that reads out and executes computer executable instructions (e.g., one or more programs) recorded on a storage medium (which may also be referred to more fully as anon-transitory computer-readable storage medium′) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2021-113492, filed on Jul. 8, 2021, which is hereby incorporated by reference herein in its entirety.

What is claimed is:

1. A photoelectric conversion device comprising:
a semiconductor layer formed of silicon;
a plurality of pixels formed in the semiconductor layer; and
a pixel separation portion is formed to separate each of the plurality of pixels, wherein
the pixel separation portion includes a metal filling portion and a dielectric film provided on a side portion of the metal filling portion,
a material of the metal filling portion is copper,
a material of the dielectric film is a silicon oxide, and
a thickness of the dielectric film is not less than 50 nm and not more than 270 nm.

2. The photoelectric conversion device according to claim 1, wherein the thickness of the dielectric film is not less than 70 nm.

3. The photoelectric conversion device according to claim 1, wherein the thickness of the dielectric film is not less than 110 nm.

4. The photoelectric conversion device according to claim 1, wherein the thickness of the dielectric film is not less than 130 nm.

5. The photoelectric conversion device according to claim 1, wherein the thickness of the dielectric film is not more than 190 nm.

6. A photoelectric conversion device comprising:
a semiconductor layer formed of silicon;
a plurality of pixels formed in the semiconductor layer; and
a pixel separation portion is formed to separate each of the plurality of pixels, wherein
the pixel separation portion includes a metal filling portion and a dielectric film provided on a side portion of the metal filling portion,
a material of the metal filling portion is tungsten,
a material of the dielectric film is a silicon oxide, and
a thickness of the dielectric film is not less than 130 nm and not more than 250 nm.

7. The photoelectric conversion device according to claim 6, wherein the thickness of the dielectric film is not less than 170 nm.

8. The photoelectric conversion device according to claim 6, wherein the thickness of the dielectric film is not less than 200 nm.

9. The photoelectric conversion device according to claim 6, wherein the thickness of the dielectric film is not more than 200 nm.

10. A photoelectric conversion device comprising:
a semiconductor layer formed of silicon;
a plurality of pixels formed in the semiconductor layer; and
a pixel separation portion is formed to separate each of the plurality of pixels, wherein
the pixel separation portion includes a metal filling portion and a dielectric film provided on a side portion of the metal filling portion,
a material of the metal filling portion is cobalt,
a material of the dielectric film is a silicon oxide, and
a thickness of the dielectric film is not less than 110 nm and not more than 270 nm.

11. The photoelectric conversion device according to claim 10, wherein the thickness of the dielectric film is not less than 170 nm.

12. The photoelectric conversion device according to claim 10, wherein the thickness of the dielectric film is not more than 210 nm.

13. A photoelectric conversion device comprising:
a semiconductor layer formed of silicon;
a plurality of pixels formed in the semiconductor layer; and
a pixel separation portion is formed to separate each of the plurality of pixels, wherein
the pixel separation portion includes a metal filling portion and a dielectric film provided on a side portion of the metal filling portion,
a material of the metal filling portion is aluminum,
a material of the dielectric film is a silicon oxide, and
a thickness of the dielectric film is not less than 60 nm and not more than 250 nm.

14. The photoelectric conversion device according to claim 13, wherein the thickness of the dielectric film is not less than 150 nm.

15. The photoelectric conversion device according to claim 13, wherein the thickness of the dielectric film is not more than 190 nm.

16. The photoelectric conversion device according to claim 1, wherein the thickness of the dielectric film is approximately 150 nm.

17. The photoelectric conversion device according to claim 1, wherein the photoelectric conversion device is a back-side-illumination solid-state imaging element.

18. The photoelectric conversion device according to claim 1, wherein, on a light incident surface side of the semiconductor layer, a periodic uneven structure portion is provided to diffract light.

19. A photoelectric conversion system comprising:
the photoelectric conversion device according to claim 1; and
a signal processing device configured to use a signal output from the photoelectric conversion device to generate an image.

20. A moving body comprising the photoelectric conversion device according to claim 1,
the moving body further comprising a control device configured to use a signal output from the photoelectric conversion device to control movement of the moving body.
